(19) United States
(12) Patent Application Publication
(10) Pub. No.: US 2026/0311775 A1
(43) Pub. Date: Oct. 8, 2026

(54) MEMORY DEVICE AND SEMICONDUCTOR DEVICE USING HIGH-LEVEL VOLTAGE

(71) Applicant: SK hynix Inc., Gyeonggi-do (KR)

(72) Inventor: Eun Woo JO, Gyeonggi-do (KR)

(21) Appl. No.: 19/292,924

(22) Filed: Aug. 7, 2025

(30) Foreign Application Priority Data
Apr. 7, 2025 (KR) 10-2025-0044468

(51) Int. Cl. G11C 16/30

(52) U.S. Cl. CPC G11C 16/30

(57) ABSTRACT

A memory device includes a switching unit configured to determine whether to transmit a high-level voltage having a level at least three times higher or greater than a power supply voltage, and a control element configured to generate, for controlling the switching unit, a first control signal transitioning between a first voltage level and a second voltage level. The first voltage level is equal to a level of the power supply voltage. The second voltage level is greater than 0 V and less than 10% of a level of the high-level voltage.

### CROSS-REFERENCE TO RELATED APPLICATIONS

This patent application claims the benefit of Korean Patent Application No. 10-2025-0044468, filed on Apr. 7, 2025, the entire disclosure of which is incorporated herein by reference.

### TECHNICAL FIELD

One or more embodiments of the present disclosure described herein relate to a memory system and a semiconductor device, and more particularly, to a memory system and a semiconductor device that use a high-level voltage having a higher voltage level than a power supply voltage.

### BACKGROUND

A data processing system including a memory system or a data storage device has been developed to store more data in the data storage device, store data in the data storage device more quickly, and output data stored in the data storage device more quickly. The data storage device may include non-volatile memory cells and/or volatile memory cells for storing data. Data storage devices can perform internal operations using a high-level voltage having a higher voltage level than a power supply voltage.

### BRIEF DESCRIPTION OF THE DRAWINGS

The description herein makes reference to the accompanying drawings wherein like reference numerals refer to like parts throughout the figures.

FIG. 1 illustrates a negative bias thermal instability (NBTI) effect occurring in a switching means according to an embodiment of the present disclosure.

FIG. 2 illustrates a memory system according to an embodiment of the present disclosure.

FIG. 3 illustrates a memory device according to an embodiment of the present disclosure.

FIG. 4 illustrates a semiconductor device according to an embodiment of the present disclosure.

FIG. 5 illustrates a memory device according to an embodiment of the present disclosure.

FIG. 6 illustrates an operation of a first switching device according to one embodiment of the present disclosure.

FIG. 7 illustrates configuration of a second switching device and a third switching device according to an embodiment of the present disclosure.

FIG. 8 illustrates an operation of a third switching device described in FIG. 7.

FIG. 9 illustrates operations of a second switching device and a third switching device according to an embodiment of the present disclosure.

FIG. 10 illustrates a first simulation result for the change in an output terminal of a switching device according to an embodiment of the present disclosure.

FIG. 11 illustrates a second simulation result for the change in an output terminal of a switching device according to an embodiment of the present disclosure.

### DETAILED DESCRIPTION

Various embodiments of the present disclosure are described below with reference to the accompanying drawings. Elements and features of this disclosure may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. Furthermore, the terms in a claim do not foreclose the apparatus from including additional components, e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. The block/unit/circuit/component used with the “configured to” language include hardware, for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

As used in this disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that they precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Herein, a data entry, an entry of data, an item of data, or a data item may be a sequence of bits. For example, the data entry may include the contents of a file, a portion of the file, a page in memory, an object in an object-oriented program, a digital message, a digital scanned image, a part of a video or audio signal, metadata or any other entity which can be represented by a sequence of bits. According to an embodiment, the data entry may include a discrete object. According to another embodiment, the data entry may include a unit of information processed or handled for a data input/output operation. According to another embodiment, the data entry may include a unit of information within a transmission packet between two different components.

Embodiments of the present disclosure can provide a memory device, a memory system including the memory device, a controller included in the memory system, or a data processing device including the memory system.

An embodiment of the present disclosure can provide an apparatus and a method for adjusting a level of a control signal used for a switching means to reduce negative bias thermal instability (NBTI), which is a deterioration phenomenon of the switching means that is configured to transmit a high-level voltage which has a higher voltage level at least three times than a power supply voltage and is used for internal operations in a semiconductor device or a memory device.

Further, an embodiment of the present disclosure can provide an apparatus and a method for selectively adjusting a voltage level of a signal that controls a switching means included in a memory device, the switching means configured to transmit a high-level signal such as a pass voltage, a program voltage, or an erase voltage, thereby reducing a deterioration phenomenon of the switching means and increasing the amount of current flowing through the switching means to obtain a gain in signal transmission.

In addition, an embodiment of the present disclosure can provide an apparatus and a method for reducing the deterioration phenomenon of a switching means included in a semiconductor device or a memory device, the switching means configured to transmit a high-level voltage having a higher voltage level at least three times than a power supply voltage, thereby improving lifespan and durability of the semiconductor device or the memory device.

In an embodiment, a memory device can include a switching unit configured to determine whether to transmit a high-level voltage having a level at least three times higher or greater than a power supply voltage; and a control element configured to generate, for controlling the switching unit, a first control signal transitioning between a first voltage level and a second voltage level. The first voltage level is equal to a level of the power supply voltage, and the second voltage level is greater than 0 V and less than 10% of a level of the high-level voltage.

The memory device can further include at least one memory cell configured to store data; a word line connected to the at least one memory cell and used to apply the high-level voltage transmitted through the switching unit; and a voltage generation circuit configured to output the high-level voltage.

The switching unit can include a PMOS transistor. The first control signal having the first voltage level or the second voltage level can be applied to a gate of the PMOS transistor.

The first control signal having the first voltage level can be used for turning off the PMOS transistor, and the second control signal having the second voltage level can be used for turning on the PMOS transistor.

The power supply voltage has a level ranging from 2.5 V to 5 V, the high-level voltage has a level of 20 V or higher, and the second voltage level is greater than 0 V and less than 2 V.

The second voltage level can be adjustable based on the levels of the power supply voltage and the high-level voltage.

The control element can be connected to a switching element configured to transmit the second voltage level to the control element in response to a selection control signal.

The switching element can include an NMOS transistor.

The switching unit can include a loop circuit which comprises a plurality of transistors and is activated in response to the second voltage; and a switch configured to discharge the loop circuit in response to a second control signal.

The second control signal can have a logical value inverted from that of the first control signal. Voltage swing ranges of the first control signal and the second control signal can be different from each other.

In another embodiment, a semiconductor device can include a switching unit configured to determine whether to transfer a high-level voltage having a level at least three times higher or greater than a power supply voltage; a control device configured to generate, for controlling the switching unit, a control signal transitioning between a first voltage level and a second voltage level; and a first switch configured to transfer, to the control device, a first low voltage level as the second voltage level in response to a first selection control signal, the first low voltage level being greater than a ground voltage level and less than a level of the high-level voltage.

The semiconductor device can further include a second switch configured to, in response to a second selection control signal, transfer the ground voltage level, as the second voltage level, to the control device. Either the first selection signal or the second selection signal can be activated.

Each of the first switch and the second switch can include a NMOS transistor.

The first voltage level can be equal to a level of the power supply voltage.

The switching unit can include a PMOS transistor. The control signal having the first voltage level or the second voltage level can be applied to a gate of the PMOS transistor.

The first control signal having the first voltage level can be used for turning off the PMOS transistor, and the second control signal having the second voltage level can be used for turning on the PMOS transistor.

The power supply voltage has a level ranging from 2.5 V to 5 V, the high-level voltage has a level of 20 V or higher, and the second voltage level is greater than 0 V and less than 2 V.

The second voltage level can be adjustable based on levels of the power supply voltage and the high-level voltage.

In another embodiment, a non-volatile memory device can include a plurality of memory cells configured to store data; a word line coupled to the plurality of memory cells; a voltage generator configured to generate at least one of a pass voltage, a program voltage, and an erase voltage, each of which individually has a level at least three times higher or greater than a power supply voltage; a switching unit configured to determine whether to transfer the at least one of the pass voltage, the program voltage, and the erase voltage to the word line; and a control element configured to generate a control signal transitioning between a first voltage level and a second voltage level to control the switching unit. The first voltage level can be equal to a level of the power supply voltage. The second voltage level can be greater than 0 V and less than 10% of a level of the high-level voltage.

The switching unit can include a PMOS transistor. The control signal having the first voltage level or the second voltage level can be applied to a gate of the PMOS transistor.

The second voltage level can be adjustable based on the levels of the power supply voltage and the high-level voltage.

Embodiments described herein can provide an apparatus and a method for improving a data input/output operation of a memory system or a data processing system. Embodiments will now be described with reference to the accompanying drawings, wherein like numbers reference like elements.

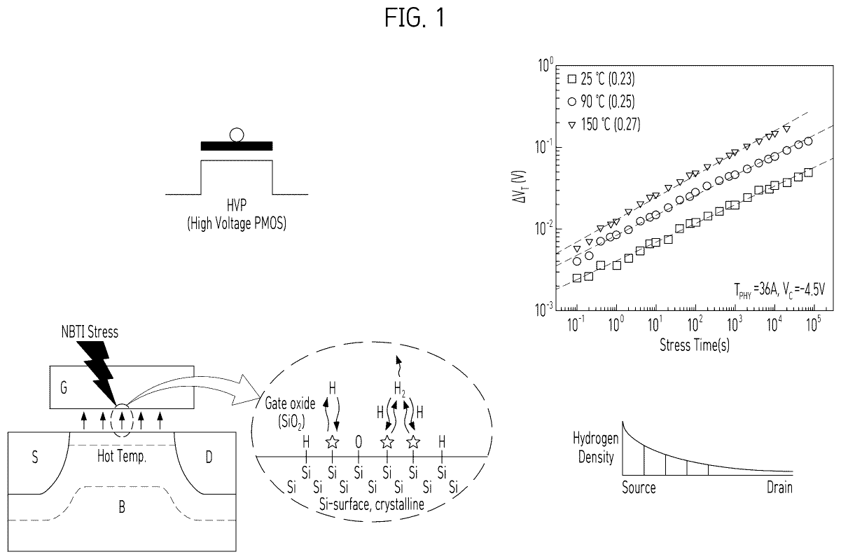

FIG. 1 illustrates a negative bias thermal instability (NBTI) effect occurring in a switching means according to an embodiment of the present disclosure.

Referring to FIG. 1, a PMOS transistor (e.g., HVP) is shown as an example of the switching means. The PMOS transistor (e.g., HVP) can be used as a switch that is configured to selectively transmit a high-level voltage VPP having a level several times higher or greater than a power supply voltage VDD.

The negative bias thermal instability (NBTI) effect that could occur in the switching means can include an increase of absolute value of threshold voltage, a mobility decrease of the p-channel MOSFET, a drain current decrease, a transconductance decrease. The negative bias thermal instability (NBTI) effect is typically found in the PMOS transistor, rather than a NMOS transistor. When the PMOS transistor is reversely biased, a silicon-hydrogen (Si—H) bond could be separated along a silicon oxide interface, generating an interface trap. Referring to a graph shown in FIG. 1, a generation rate of such traps could be accelerated depending on a temperature ΔV_{T}(V) and an applied stress time (i.e., Stress Time(s)). Such traps could increase the threshold voltage Vth of the PMOS transistor. An increase in the threshold voltage Vth can worsen a delay in a circuit or an element including the switching means. If a delay value of the circuit or the element exceeds a certain amount due to the worsening of the delay, the circuit or the element might not meet timing specifications of signals received from, transmitted by, or processed by another circuit or element.

The occurrence mechanism of the negative bias thermal instability (NBTI) effect could be initiated from degradation of the silicon-hydrogen (Si—H) bond broken due to a chemical reaction with high-energy holes on the SiO₂/Si surface. For example, if a voltage (e.g., Vgs) between a gate and a source in the PMOS transistor is a negative value (e.g., −Vdd), an interface trap could occur. If the voltage (e.g., Vgs) between the gate and the source is ‘0’, the interface trap could be reduced. Therefore, the negative bias thermal instability (NBTI) effect on the PMOS transistor could vary depending on a time that the PMOS transistor is stressed and relaxed.

Generally, two types of traps are known to contribute to the negative bias thermal instability (NBTI) effect. First, when the voltage (e.g., Vgs) between the gate and the source is negative, an interface trap could be generated. The interface trap might be difficult to be recovered during a reasonable operating time including when the voltage (e.g., Vgs) between the gate and the source becomes ‘0’. The electric field can break the silicon-hydrogen (Si—H) bonds located at the silicon-oxide interface. The hydrogen (e.g., H, H₂) can be released from a moving substrate, while remaining unsaturated bonds (e.g., dangling bonds at the Si-Pb center) could lead to a deterioration of the threshold voltage V_{TH}.

In addition, as more interface traps are created, the hydrogen (e.g., H, H₂) could diffuse from the source to the drain. As shown in FIG. 1, a hydrogen density from the source to the drain in the PMOS transistor could be formed.

In addition to generation of interface traps, existing (e.g., nitrogen-related) traps located in most of the dielectric could be filled with holes from the PMOS channel. When the stress voltage is removed, these traps could be emptied. This deterioration of the threshold voltage Vth could be recovered over time.

As described above, the negative bias thermal instability (NBTI) effect could occur as the interface between the gate insulator (e.g., Gox) and the substrate is deteriorated when a negative bias stress and a temperature-related stress are applied to the PMOS transistor. This deterioration could increase the threshold voltage Vth. Specifically, when a negative bias is applied, holes could be injected into an interface of Si/SiO₂. The silicon-hydrogen (Si—H) bond could be broken by the holes which can generate hydrogen ions (e.g., H+). When diffusion/drift of the hydrogen ions occurs, an interface trap (positive) can occur at a site of the hydrogen ions. The interface trap as a positive charge can further lower the absolute value of threshold voltage Vth of the PMOS transistor. Further, when the threshold voltage Vth is positive, an absolute value of the threshold voltage V_{TH} could be increased.

The negative bias thermal instability (NBTI) effect that may occur in the switching means adversely affects a normal operation of a semiconductor device, a memory device, or a memory system. The effect might be critical because the PMOS transistors can be often used as switching means in semiconductor devices, memory devices, or memory systems. In particular, as described in FIG. 1, the semiconductor device, memory device, or memory system can include a switching means configured to transmit the high-level voltage. Deterioration, malfunction, or increased delay of the switching means can interfere with the normal operation of the semiconductor device, memory device, or memory system.

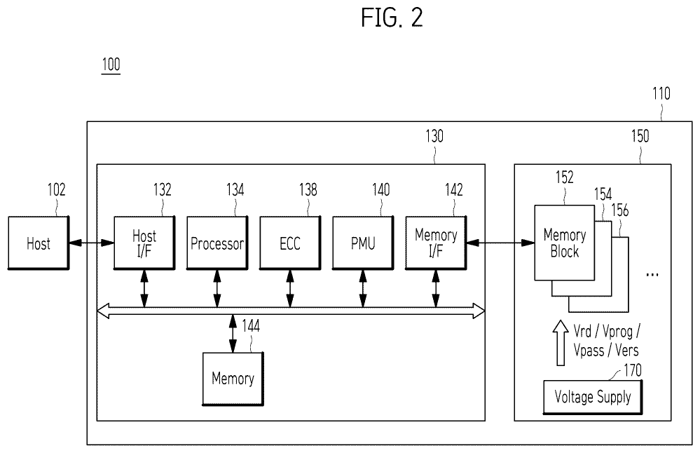

FIG. 2 illustrates a memory system according to an embodiment of the present disclosure.

Referring to FIG. 2, the data processing system 100 may include a host 102 engaged or coupled with a memory system, such as memory system 110. For example, the host 102 and the memory system 110 may be coupled to each other via a data bus, a host cable, and the like, to perform data communication.

The memory system 110 may include a memory device 150 and a controller 130. The memory device 150 and the controller 130 in the memory system 110 may be considered components or elements physically separated from each other. The memory device 150 and the controller 130 may be connected via at least one data path. For example, the data path may include a channel and/or a way.

According to an embodiment, the memory device 150 and the controller 130 may be components or elements functionally divided. Further, according to an embodiment, the memory device 150 and the controller 130 may be implemented with a single chip or a plurality of chips. The controller 130 may perform a data input/output operation in response to a request input from the external device. For example, when the controller 130 performs a read operation in response to a read request input from an external device, data stored in a plurality of non-volatile memory cells included in the memory device 150 is transferred to the controller 130.

As shown in FIG. 2, the memory device 150 may include a plurality of memory blocks 152, 154, 156. The memory blocks 152, 154, 156 may be understood as a group of non-volatile memory cells in which data is removed together by a single erase operation. Although not illustrated, the memory blocks 152, 154, 156 may include a page which is a group of non-volatile memory cells that store data together during a single program operation or output data together during a single read operation. For example, one memory block may include a plurality of pages.

For example, the memory device 150 may include a plurality of memory planes or a plurality of memory dies. According to an embodiment, the memory plane may be considered a logical or a physical partition including at least one memory block, a driving circuit capable of controlling an array including a plurality of non-volatile memory cells, and a buffer that can temporarily store data input to, or output from, non-volatile memory cells.

In addition, according to an embodiment, the memory die may include at least one memory plane. The memory die may be understood to be a set of components implemented on a physically distinguishable substrate. Each memory die may be connected to the controller 130 through a data path. Each memory die may include an interface to exchange an item of data and a signal with the controller 130.

According to an embodiment, the memory device 150 may include at least one memory block 152, 154, 156, at least one memory plane, or at least one memory die. The internal configuration of the memory device 150 shown in FIG. 2 may be different according to the configuration, performance, and/or design of the memory system 110. An embodiment of the present disclosure is not limited to the internal configuration shown in FIG. 2.

Referring to FIG. 2, the memory device 150 may include a voltage supply circuit 170 capable of supplying at least some voltage into the memory block 152, 154, 156. The voltage supply circuit 170 may supply a read voltage Vrd, a program voltage Vprog, a pass voltage Vpass, or an erase voltage Vers into a non-volatile memory cell included in the memory block. For example, during a read operation for reading data stored in the non-volatile memory cell included in the memory block 152, 154, 156, the voltage supply circuit 170 may supply the read voltage Vrd into a selected non-volatile memory cell. During the program operation for storing data in the non-volatile memory cell included in the memory block 152, 154, 156, the voltage supply circuit 170 may supply the program voltage Vprog into a selected non-volatile memory cell. Also, during a read operation or a program operation performed on the selected nonvolatile memory cell, the voltage supply circuit 170 may supply a pass voltage Vpass into a non-selected nonvolatile memory cell. During the erasing operation for erasing data stored in the non-volatile memory cell included in the memory block 152, 154, 156, the voltage supply circuit 170 may supply the erase voltage Vers into the memory block.

According to an embodiment, the program voltage Vprog, the pass voltage Vpass, or the erase voltage Vers applied by the voltage supply circuit 170 to the at least one memory block 152, 154, 156 through at least one word line can be included in the high-level voltage VPP described in FIG. 1. The program voltage Vprog, the pass voltage Vpass, or the erase voltage Vers can have a potential that is several times higher than the power supply voltage.

The memory device 150 may store information regarding various voltages which are supplied to the memory block 152, 154, 156 based on which an operation is performed. For example, when a non-volatile memory cell in the memory block 152, 154, 156 can store multi-bit data, plural levels of the read voltage Vrd for recognizing or reading the multi-bit data entry may be required. The memory device 150 may include a table including information corresponding to plural levels of the read voltage Vrd, corresponding to the multi-bit data entry. For example, the table may include bias values stored in a register, each bias value corresponding to a specific level of the read voltage Vrd. The number of bias values for the read voltage Vrd that is used for a read operation may be limited to a preset range. Also, the bias values may be quantified (or quantized).

The host 102 may include a portable electronic device, e.g., a mobile phone, an MP3 player, a laptop computer, etc., or a non-portable electronic device, e.g., a desktop computer, a game player, a television, a projector, etc.

The host 102 may also include at least one operating system (OS), which may control functions and operations performed in the host 102. The OS may provide interoperability between the host 102 engaged operatively with the memory system 110 and a user who intends to store data in the memory system 110. The OS may support functions and operations corresponding to user's requests. By way of example but not limitation, the OS may be classified into a general operating system and a mobile operating system according to mobility of the host 102. The general operating system may be further classified into a personal operating system and an enterprise operating system according to system requirements or a user environment. As compared with the personal operating system, the enterprise operating systems can be specialized for securing and supporting high performance computing.

The mobile operating system may be subject to support services or functions for mobility, e.g., a power saving function. The host 102 may include a plurality of operating systems. The host 102 may execute multiple operating systems interlocked with the memory system 110, corresponding to a user's request. The host 102 may transmit a plurality of commands corresponding to the user's requests into the memory system 110, thereby performing operations corresponding to the plurality of commands within the memory system 110.

A controller 130 in the memory system 110 may control a memory device 150 in response to a request or a command input from the host 102. For example, the controller 130 may perform a read operation to provide data read from the memory device 150 to the host 102 and may perform a write operation (or a program operation) to store data input from the host 102 in the memory device 150. In order to perform data input/output (I/O) operations, the controller 130 may control and manage internal operations of reading data, programming data, erasing data, or the like.

According to an embodiment, the controller 130 may include a host interface 132, a processor 134, an error correction circuitry (ECC) 138, a power management unit (PMU) 140, a memory interface (I/F) 142, and a memory 144. Components included in the controller 130 as illustrated in FIG. 2 may vary according to structures, functions, operation performance, or the like, implemented in (or associated with, configured for) the memory system 110.

For example, the memory system 110 may be implemented with any of various types of storage devices, which may be electrically coupled with the host 102, according to a protocol of a host interface. Non-limiting examples of suitable storage devices include a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) storage device, a universal flash storage (UFS) device, a compact flash (CF) card, a smart media (SM) card, a memory stick, and the like. Components may be added to or omitted from the controller 130 according to an embodiment of the memory system 110.

The host 102 and the memory system 110 each may include a controller or an interface for transmitting and receiving signals, data, and the like, in accordance with one or more predetermined protocols. For example, the host interface 132 in the memory system 110 may include an apparatus capable of transmitting signals, data, and the like to the host 102 or receiving signals, data, and the like from the host 102.

The host interface 132 included in the controller 130 may receive signals, commands (or requests), and/or data input from the host 102 via a bus. For example, the host 102 and the memory system 110 may use a predetermined set of rules or procedures for data communication or a preset interface to transmit and receive data therebetween. Examples of sets of rules or procedures for data communication standards or interfaces supported by the host 102 and the memory system 110 for sending and receiving data include Universal Serial Bus (USB), Multi-Media Card (MMC), Parallel Advanced Technology Attachment (PATA), Small Computer System Interface (SCSI), Enhanced Small Disk Interface (ESDI), Integrated Drive Electronics (IDE), Peripheral Component Interconnect Express (PCIe or PCI-e), Serial-attached SCSI (SAS), Serial Advanced Technology Attachment (SATA), Mobile Industry Processor Interface (MIPI), and the like. According to an embodiment, the host interface 132 may be a type of layer for exchanging data with the host 102 and may be implemented with, or driven by, firmware such as a host interface layer (HIL). According to an embodiment, the host interface 132 may include a command queue.

An Integrated Drive Electronics (IDE) interface or an Advanced Technology Attachment (ATA) interface may be used as one of the interfaces for transmitting and receiving data and, for example, may use a cable including 40 wires connected in parallel to support data transmission and data reception between the host 102 and the memory system 110. When a plurality of memory systems 110 are connected to a single host 102, the plurality of memory systems 110 may be divided into a master and a slave by using a position or a dip switch to which the plurality of memory systems 110 are connected. The memory system 110 set as the master may be used as a main memory device. The IDE (ATA) may include, for example, Fast-ATA, ATAPI, or Enhanced IDE (EIDE).

A Serial Advanced Technology Attachment (SATA) interface is a type of serial data communication interface that is compatible with various ATA standards of parallel data communication interfaces which are used by Integrated Drive Electronics (IDE) devices. The 40 wires in the IDE interface can be reduced to six wires in the SATA interface. For example, 40 parallel signals for the IDE may be converted into 6 serial signals for the SATA interface. The SATA interface has been widely used because of its faster data transmission and reception rate and its less resource consumption in the host 102 used for data transmission and reception. The SATA interface may connect up to 30 external devices to a single transceiver included in the host 102. In addition, the SATA interface may support hot plugging that allows an external device to be attached to or detached from the host 102, even while data communication between the host 102 and another device is being executed. Thus, the memory system 110 can be connected or disconnected as an additional device, like a device supported by a universal serial bus (USB) even when the host 102 is powered on. For example, in the host 102 having an eSATA port, the memory system 110 may be freely attached to or detached from the host 102 in the manner of (attaching and detaching) an external hard disk.

Small Computer System Interface (SCSI) is a type of serial data communication interface used for connecting a computer or a server with other peripheral devices. The SCSI can provide a high transmission speed, as compared with other interfaces such as IDE and SATA. In (combined) systems that implement SCSI, the host 102 and at least one peripheral device (e.g., memory system 110) are connected in series, but data transmission and reception between the host 102 and each peripheral device may be performed through parallel data communication (or a parallel data connection). In the systems that implement SCSI, devices such as the memory system 110 may be easily (for example, with stability and/or minimal processing or adjustment required) connected to or disconnected from the host 102. The SCSI can support connections of 15 other devices to a single transceiver included in host 102.

Serial Attached SCSI (SAS) may be understood to be a serial data communication version of the SCSI. In the SAS, the host 102 and a plurality of peripheral devices are connected in series, and data transmission and reception between the host 102 and each peripheral device may be performed (or executed) in a serial data communication scheme. The SAS may support connection between the host 102 and the peripheral device through a serial cable instead of a parallel cable, to easily (for example, in a timely manner without additional processes, protocol or devices, etc.) manage equipment using the SAS and enhance or improve operational reliability and communication performance. The SAS may support connections of eight external devices to a single transceiver included in the host 102.

The Non-volatile memory express (NVMe) is a type of interface based at least on a Peripheral Component Interconnect Express (PCIe) designed to increase performance and design flexibility of the host 102, servers, computing devices, and the like equipped with the non-volatile memory system 110. The PCIe may use a slot or a specific cable for connecting a computing device (e.g., host 102) and a peripheral device (e.g., memory system 110). For example, the PCIe may use a plurality of pins (e.g., 18 pins, 32 pins, 49 pins, or 82 pins) and at least one wire (e.g., ×1, ×4, ×8, or ×16) to achieve high speed data communication over several hundred MB per second (e.g., 250 MB/s, 500 MB/s, 984.6250 MB/s, or 1969 MB/s). According to an embodiment, the PCIe scheme may achieve bandwidths of tens to hundreds of Giga bits per second. The NVMe may support an operation speed of the non-volatile memory system 110, such as an SSD, that is faster than a hard disk.

According to an embodiment, the host 102 and the memory system 110 may be connected through a universal serial bus (USB). The Universal Serial Bus (USB) is a type of scalable, hot-pluggable plug-and-play serial interface that can provide cost-effective standard connectivity between the host 102 and peripheral devices such as a keyboard, a mouse, a joystick, a printer, a scanner, a storage device, a modem, a video camera, and the like. A plurality of peripheral devices such as the memory system 110 may be coupled to a single transceiver included in the host 102.

Referring to FIG. 2, the error correction circuitry 138 may correct error bits of data read from the memory device 150, and may include an error correction code (ECC) encoder and an ECC decoder. The ECC encoder may perform error correction encoding of data to be programmed in the memory device 150 to generate encoded data into which a parity bit is added, and store the encoded data in the memory device 150. The ECC decoder may detect and correct error bits contained in the data read from the memory device 150 when the controller 130 reads the data stored in the memory device 150. For example, after performing error correction decoding on the data read from the memory device 150, the error correction circuitry 138 determines whether the error correction decoding has succeeded or not, and outputs an instruction signal, e.g., a correction success signal or a correction fail signal, based on a result of the error correction decoding. The error correction circuitry 138 may use a parity bit, which has been generated during the ECC encoding process for the data stored in the memory device 150, in order to correct the error bits of the read data entries. When the number of the error bits is greater than or equal to the number of correctable error bits, the error correction circuitry 138 may not correct the error bits and may instead output the correction fail signal indicating a failure in correcting the error bits.

According to an embodiment, the error correction circuitry 138 may perform an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), or the like. The error correction circuitry 138 may include all circuits, modules, systems, and/or devices for performing the error correction operation based on at least one of the above-described codes.

For example, the ECC decoder may perform hard decision decoding or soft decision decoding on data transmitted from the memory device 150. The hard decision decoding can be understood as one of two methods broadly classified for error correction. The hard decision decoding may include an operation of correcting an error bit by reading digital data of ‘0’ or ‘1’ from a non-volatile memory cell in the memory device 150. Because the hard decision decoding handles a binary logic signal, the circuit/algorithm design or configuration may be simpler than the soft decision decoding, and a processing speed may be faster than the soft decision decoding.

The soft decision decoding may quantize a threshold voltage of a non-volatile memory cell in the memory device 150 by two or more quantized values, e.g., multiple bit data, approximate values, an analog value, and the like, in order to correct an error bit based on the two or more quantized values. The controller 130 may receive two or more alphabets or quantized values from a plurality of non-volatile memory cells in the memory device 150, and then perform a decoding based on information generated by characterizing the quantized values as a combination of information such as conditional probability or likelihood.

According to an embodiment, the ECC decoder may use a low-density parity-check and generator matrix (LDPC-GM) code among methods designed for the soft decision decoding. The low-density parity-check (LDPC) code uses an algorithm that can read values of data from the memory device 150 in several bits according to reliability, not simply data of 1 or 0 in the manner of the hard decision decoding, and iteratively repeats the process through a message exchange in order to improve reliability of the values. Then, the values are finally determined as data of 1 or 0. For example, a decoding algorithm using LDPC codes can be understood as probabilistic decoding. In the hard decision decoding, a value output from a non-volatile memory cell may be decoded as 0 or 1. Compared to the hard decision decoding, the soft decision decoding can determine the value stored in the non-volatile memory cell based on the stochastic information. Regarding bit-flipping which may be considered an error that can occur in the memory device 150, the soft decision decoding may provide improved probability of correcting the error and recovering data, as well as providing reliability and stability of corrected data. The LDPC-GM code may have a scheme in which internal LDGM codes can be concatenated in series with high-speed LDPC codes.

According to an embodiment, the ECC decoder may use, for example, low-density parity-check convolutional codes (LDPC-CCs) for the soft decision decoding. The LDPC-CCs may have a scheme using a linear time encoding and a pipeline decoding based on a variable block length and a shift register.

According to an embodiment, the ECC decoder may use, for example, a Log Likelihood Ratio Turbo Code (LLR-TC) for the soft decision decoding. A Log Likelihood Ratio (LLR) may be calculated as a non-linear function for a distance between a sampled value and an ideal value. In addition, a Turbo Code (TC) may include a simple code, for example, a Hamming code, in two or three dimensions and repeat decoding in a row direction and a column direction to improve reliability of values.

The power management unit (PMU) 140 may control electrical power provided to the controller 130. The PMU 140 may monitor the electrical power supplied to the memory system 110, e.g., a voltage supplied to the controller 130, and provide the electrical power to components included in the controller 130. The PMU 140 may not only detect power-on or power-off, but also generate a trigger signal to enable the memory system 110 to urgently back up a current state when the electrical power supplied to the memory system 110 is unstable. According to an embodiment, the PMU 140 may include a device or a component capable of accumulating electrical power that may be used in an emergency.

The memory interface (I/F) 142 may serve as an interface for handling commands and data transferred between the controller 130 and the memory device 150, in order to allow the controller 130 to control the memory device 150 in response to a command or a request input from the host 102. The memory interface 142 may generate a control signal for the memory device 150 and may process data input to, or output from, the memory device 150 under the control of the processor 134 in a case when the memory device 150 is a flash memory.

For example, when the memory device 150 includes a NAND flash memory, the memory interface 142 includes a NAND flash controller (NFC). The memory interface 142 can provide an interface for handling commands and data between the controller 130 and the memory device 150. In accordance with an embodiment, the memory interface 142 can be implemented through, or driven by, firmware called a Flash Interface Layer (FIL) for exchanging data with the memory device 150.

According to an embodiment, the memory interface 142 may support an open NAND flash interface (ONFi), a toggle mode, or the like, for data input/output with the memory device 150. For example, the ONFi may use a data path (e.g., a channel, a way, etc.) that includes at least one signal line capable of supporting bi-directional transmission and reception in a unit of 8-bit or 16-bit data. Data communication between the controller 130 and the memory device 150 can be achieved through at least one interface regarding an asynchronous single data rate (SDR), a synchronous double data rate (DDR), a toggle double data rate (DDR), or the like.

The memory 144 may be used as a working memory of the memory system 110 or the controller 130, while temporarily storing transactional data for operations performed in the memory system 110 and the controller 130. For example, the memory 144 may temporarily store read data entries output from the memory device 150 in response to a read request from the host 102 before the read data entries are output to the host 102. In addition, the controller 130 may temporarily store write data entries input from the host 102 in the memory 144 before programming the write data entries in the memory device 150. When the controller 130 controls operations, such as a data read operation, a data write or program operation, a data erase operation, etc., of the memory device 150, data transmitted between the controller 130 and the memory device 150 of the memory system 110 may be temporarily stored in the memory 144.

In addition to the read data entries or write data entries, the memory 144 may store information, e.g., map data, read requests, program requests, etc. used for inputting or outputting data between the host 102 and the memory device 150. According to an embodiment, the memory 144 may include one or more of a command queue, a program memory, a data memory, a write buffer/cache, a read buffer/cache, a data buffer/cache, a map buffer/cache, and so on. The controller 130 may allocate some storage space in the memory 144 for a component which is established to carry out a data input/output operation. For example, the write buffer established in the memory 144 may be used to temporarily store target data subject to a program operation.

In an embodiment, the memory 144 may be implemented with a volatile memory. For example, the memory 144 may be implemented with a static random access memory (SRAM), a dynamic random access memory (DRAM), or both. Although FIG. 2 illustrates, for example, the memory 144 disposed within the controller 130, embodiments are not limited thereto. The memory 144 may be located within or external to the controller 130. For instance, the memory 144 may be embodied by an external volatile memory having a memory interface transferring data and/or signals between the memory 144 and the controller 130.

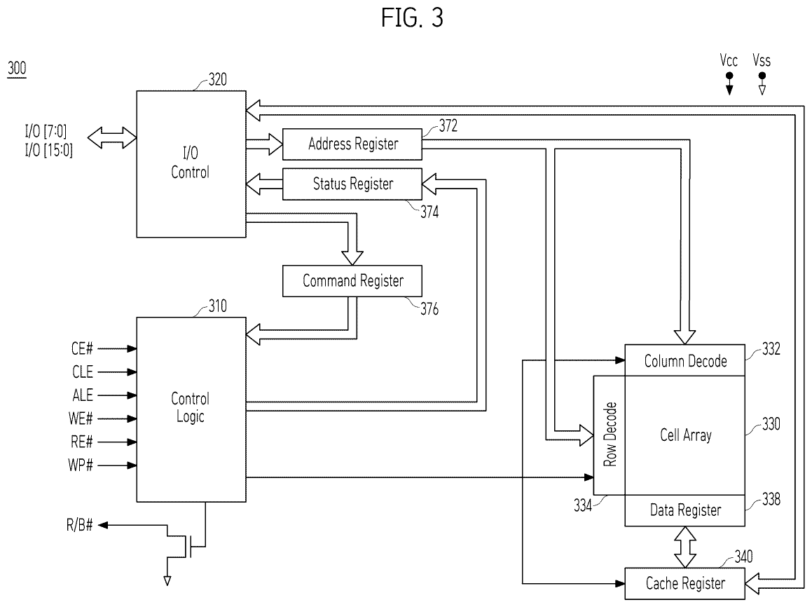

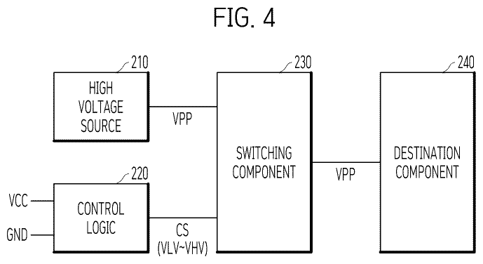

The processor 134 may control the overall operations of the memory system 110. For example, the processor 134 may control a program operation or a read operation of the memory device 150 in response to a write request or a read request entered from the host 102. According to an embodiment, the processor 134 may execute firmware to control the program operation or the read operation in the memory system 110. Herein, the firmware may be referred to as a flash translation layer (FTL). An example of the FTL will be described in detail, referring to FIGS. 3 and 4. According to an embodiment, the processor 134 may be implemented with a microprocessor, a central processing unit (CPU), or the like.

According to an embodiment, the memory system 110 may be implemented with at least one multi-core processor. The multi-core processor is a type of circuit or chip in which two or more cores, which are considered distinct processing regions, are integrated. For example, when a plurality of cores in the multi-core processor drive or execute a plurality of flash translation layers (FTLs) independently, a data input/output speed (or performance) of the memory system 110 may be improved. According to an embodiment, the data input/output (I/O) operations in the memory system 110 may be independently performed through different cores in the multi-core processor.

The processor 134 in the controller 130 may perform an operation corresponding to a request or a command input from the host 102. Further, the memory system 110 may perform an operation independent from a command or a request input from the host 102. In one case, an operation performed by the controller 130 in response to the request or the command input from the host 102 may be considered a foreground operation, while an operation performed by the controller 130 independently from the request or the command input from the host 102 may be considered a background operation. The controller 130 may perform foreground or background operations for reading, writing, or erasing data in the memory device 150. In addition, a parameter set operation corresponding to a set parameter command or a set feature command as a set command transmitted from the host 102 may be considered a foreground operation. Background operations that can be performed without a command transmitted from the host 102 by the controller 130 include garbage collection (GC), wear leveling (WL), bad block management for identifying and processing bad blocks, or the like.

According to an embodiment, substantially similar operations may be performed as both the foreground operation and the background operation. For example, when the memory system 110 performs garbage collection in response to a request or a command input from the host 102 (e.g., Manual GC), the garbage collection can be considered a foreground operation. When the memory system 110 performs garbage collection independently of the host 102 (e.g., Auto GC), the garbage collection can be considered a background operation.

When the memory device 150 includes a plurality of dies (or a plurality of chips) each including a plurality of non-volatile memory cells, the controller 130 may perform parallel processing regarding plural requests or commands input from the host 102 in order to improve performance of the memory system 110. For example, the transmitted requests or commands may be divided into plural groups including at least some of a plurality of planes, a plurality of dies, or a plurality of chips included in the memory device 150, and the plural groups of requests or commands may be processed individually or in parallel in each plane, each die or each chip.

The memory interface 142 in the controller 130 may be connected to the plurality of dies or chips in the memory device 150 through at least one channel and at least one way. When the controller 130 distributes and stores data in the plurality of dies through each channel or each way in response to requests or commands associated with a plurality of pages including non-volatile memory cells, a plurality of operations corresponding to the requests or the commands can be performed simultaneously or in parallel in the plurality of dies or planes. Such a processing method or scheme can be described as an interleaving method. Because a data input/output speed of the memory system 110 increases by operating with the interleaving method, data I/O performance of the memory system 110 can be improved.

By way of example but not limitation, the controller 130 may recognize statuses of a plurality of channels (or ways) associated with the plurality of dies included in the memory device 150. The controller 130 may determine a status of each channel or each connection as one of a busy status, a ready status, an active status, an idle status, a normal status, and an abnormal status. The determination of which channel or connection an instruction (and/or a data) is delivered through by the controller can be associated with a physical block address. The controller 130 may refer to descriptors delivered from the memory device 150. The descriptors may include a block or page of parameters describing something about the memory device 150. The descriptors can have a predetermined format or structure. For instance, the descriptors may include device descriptors, configuration descriptors, unit descriptors, and the like. The controller 130 may refer to, or use, the descriptors to determine which channel(s) or way(s) is used to exchange an instruction or data.

Referring to FIG. 2, the memory device 150 in the memory system 110 may include a plurality of memory blocks 152, 154, 156. Each of the plurality of memory blocks 152, 154, 156 includes a plurality of non-volatile memory cells. According to an embodiment, the memory block 152, 154, 156 can be a group of non-volatile memory cells erased together. The memory block 152, 154, 156 may include a plurality of pages which is a group of non-volatile memory cells read or programmed together.

According to an embodiment, each memory block 152, 154, or 156 may have a three-dimensional stack structure for a high integration. Further, the memory device 150 may include a plurality of dies, each die including a plurality of planes, each plane including the plurality of memory blocks 152, 154, 156. A configuration of the memory device 150 may be changed depending on performance of the memory system 110.

FIG. 2 illustrates the memory device 150 that includes the plurality of memory blocks 152, 154, 156. The plurality of memory blocks 152, 154, 156 may be any of single-level cell (SLC) memory blocks, multi-level cell (MLC) memory blocks, or the like, according to the number of bits that can be stored in one memory cell. An SLC memory block includes a plurality of pages implemented by memory cells, each memory cell storing one bit of data. An SLC memory block may have higher data I/O operation performance and higher durability than the MLC memory block. The MLC memory block includes a plurality of pages implemented by memory cells, each memory cell storing multi-bit data, e.g., two or more bits of data. The MLC memory block may have larger storage capacity for the same space compared to the SLC memory block. The MLC memory block can be highly integrated in a view of storage capacity.

According to an embodiment, the memory device 150 may be implemented with MLC memory blocks such as a double level cell (DLC) memory block, a triple-level cell (TLC) memory block, a quadruple-level cell (QLC) memory block, and a combination thereof. The DLC memory block may include a plurality of pages implemented by memory cells, each memory cell capable of storing 2-bit data. The TLC memory block can include a plurality of pages implemented by memory cells, each memory cell capable of storing 3-bit data. The QLC memory block may include a plurality of pages implemented by memory cells, each memory cell capable of storing 4-bit data. In another embodiment, the memory device 150 may be implemented with a block including a plurality of pages implemented by memory cells, each memory cell capable of storing five or more bits of data.

According to an embodiment, the controller 130 may use an MLC memory block included in the memory device 150 as an SLC memory block that stores one-bit data in one memory cell. A data input/output speed of the multi-level cell (MLC) memory block can be slower than that of the SLC memory block. That is, when the MLC memory block is used as the SLC memory block, a margin for a read or program operation can be reduced. For example, the controller 130 may perform a data input/output operation with a higher speed when the MLC memory block is used as the SLC memory block. Thus, the controller 130 may use the MLC memory block as a SLC buffer to temporarily store data because the buffer may require a high data input/output speed for improving performance of the memory system 110.

Further, according to an embodiment, the controller 130 can program data in an MLC a plurality of times without performing an erase operation on a specific MLC memory block included in the memory device 150. In general, non-volatile memory cells do not support data overwrite. However, the controller 130 may program 1-bit data in the MLC a plurality of times using a feature in which the MLC is capable of storing multi-bit data. For an MLC overwrite operation, the controller 130 may store the number of program times as separate operation information when 1-bit data is programmed in an MLC. According to an embodiment, an operation for uniformly levelling threshold voltages of the MLCs may be carried out before another 1-bit data is programmed in the same MLCs, each having stored 1-bit data.

According to an embodiment, the memory device 150 may be embodied as a non-volatile memory such as a flash memory, for example, a NAND flash memory, a NOR flash memory, or the like. In another embodiment, the memory device 150 may be implemented by at least one of a programmable ROM (PROM), an erasable ROM (EPROM), an electrically erasable ROM (EEPROM), a phase change RAM (PRAM), a magnetic RAM (MRAM), a Resistive RAM (RRAM) a phase change random access memory (PCRAM), a ferroelectrics random access memory (FRAM), a spin transfer torque random access memory (STT-RAM), and a spin transfer torque magnetic random access memory (STT-MRAM), or the like.

FIG. 3 illustrates a memory device 300 according to an embodiment of the present disclosure. The memory device 300 described in FIG. 3 can be understood as an embodiment of the memory device 150 described in FIG. 2.

Referring to FIG. 3, the memory device 300 can include at least one memory die. The memory device 300 can receive or output a plurality of control signals such as chip enable CE #, command latch enable CLE, address latch enable ALE, write enable WE #, read enable RE #, write protect WP #, ready/busy R/B #, and receive or transmit data or operation information through channels I/O[7:0], I/O[15:0]. For example, a predetermined amount of data (e.g., 1 byte (8 bits) or 2 bytes (16 bits)) can be transmitted and received according to a channel (e.g., I/O[7:0], I/O[15:0]) connecting the memory device 300 and a controller such as the controller 130 shown in FIG. 2.

According to an embodiment, the memory device 300 may include a plurality of pins or pads. For example, the plurality of control signals CE #, CLE, ALE, WE #, RE #, WP #, R/B #can be transmitted or received through exclusively allocated pins. The control signals may include a chip enable signal CE #, a command latch enable signal CLE, an address latch enable signal ALE, a write enable signal WE #, a read enable signal RE #, a write protect signal WP #, a status signal R/B # indicating a ready state or a busy state, and the like. The control signals CE #, CLE, ALE, WE #, RE #, WP #, R/B # can be controlled (transmitted and received) by control circuitry 310 included in the memory device 300.

A control circuit 310 may perform preset operations in response to commands and addresses input to the memory device 300. For example, when a read command is received, the control circuit 310 may manage and control components in the memory device 300 to sequentially perform operations or tasks corresponding to the read command. In addition, when the controller 130 described in FIG. 2 transmits a command to check an operation status of the memory device 300, the control circuit 310 may check information regarding the operation status and output the information to the controller 130. The control circuit 310 may be configured to perform an operation or task corresponding to a specific command or a specific interrupt according to a preset procedure in response to an input command or the interrupt, and then transmit a result of the operation or task.

The memory device 300 can include an input and output (input/output (I/O)) control circuit 320. The input/output control circuit 320 can be connected to other devices or components (e.g., a controller) through the channels I/O[7:0], I/O[15:0]. The input/output control circuit 320 in the memory device 300 can be coupled to a plurality of registers 372, 374, 376 and a cache register 340 coupled to a cell array 330.

According to an embodiment, the input/output control circuit 320 can include a chip select decoder, while the memory device 300 may include a plurality of memory chips. A chip select function may be used to activate one of the plurality of memory chips included in or connected to a memory system or a data processing system. Depending on the embodiment, the chip select decoder may be implemented with combinational logic gates that activate one specific output line in response to an input binary code. The memory system or the data processing system can use an activated output line to activate or “select” a specific chip or device from multiple devices connected to the memory system or the data processing system. For example, if there are multiple memory chips on a same bus (such as flash memory chips in solid state drives (SSDs)), for most operations it is impossible to communicate with all memory chips simultaneously because data entries or commands sent across the bus could be routed to all memory chips. Instead, a chip select signal can be used to select which chip to communicate with at any given time. The chip select decoder can manage and control data communication between multiple devices (e.g., the multiple memory chips) that share the same bus or connection lines in a system by activating one specific device based on an input select code or signal.

According to an embodiment, the memory device 300 can include the cache register 340, an address register 372, a status information register 374, and a command register 376. The cache register 340 can temporarily store data. When the memory device 300 performs a read operation, the cache register 340 can store a read data entry output from the cell array 330. When the memory device 300 performs a write operation or a program operation, the cache register 340 can store a write data entry. The address register 372 can store an address indicating a location of the cell array 330 where a read operation or a write operation is to be performed. The command register 376 can store a command to be executed by the memory device 300. The status information register 374 can store status information such as a result (failure/success) of an operation performed in the memory device 300 or readiness for performing an operation. For example, when a plurality of memory planes is included in a memory die in the memory device 300, the status information register 374 can store status information regarding each of the plurality of memory planes. Data, commands, and information transmitted or received through the input/output control circuit 320 in the memory device 300 can be controlled (e.g., transmitted, moved, or output) by the control circuitry 310.

During a read operation in the memory device 300, a row decoder 334 and a column decoder 332 can select one or more memory cells in the cell array 330 based on an address stored in the address register 372 and a control signal from the control circuitry 310. During a read operation, a read data entry output from the cell array 330 may be stored in the data register 338 and then transferred from the data register 338 to the cache register 340. The read data entry stored in the cache register 340 may be transferred to the input/output control circuit 320 through input/output lines. The read data entry transmitted to the input/output control circuit 320 may be output to the controller through the channels I/O[7:0], I/O[15:0].

During a write operation or a program operation in the memory device 300, the row decoder 334 and the column decoder 332 can select one or more memory cells in the cell array 330 in response to an address stored in the address register 372 and a control signal from the control circuitry 310. During the write operation, the write data entry transferred from the controller to the input/output control circuit 320 through the channels I/O[7:0], I/O[15:0] can be stored in the cache register 340. Thereafter, the write data entry may be transferred from the cache register 340 to the data register 338. The write data entry stored in the data register 338 can be programmed in selected memory cells in the cell array 330 by the control circuitry 310.

The data register 338 and the cache register 340 can be included in a read/write circuit comprising a sense amplifier, a page buffer, or the like. According to an embodiment, page buffers or data latches included in the memory device 300 can correspond to the data register 338 and/or the cache register 340. Further, the cache register 340 is configured to temporarily store data transmitted between the data register 338 and the input/output control circuit 320. The cache register 340 may have a pipe latch structure depending on the embodiment.

A pipeline (or pipelining) system including at least one pipe latch can include an apparatus that can parallelize a plurality of data entries input and output serially. According to an embodiment, the pipeline system is applicable to the input/output control circuit 320 or the cache register 340. Further, according to an embodiment, the pipeline system may be used to compensate for delays and noise occurring in a data transmission process as a data path through which data is transmitted within the memory device 300 of the memory system becomes longer.

The cell array 330 shown in FIG. 3 can have a two-dimensional or three-dimensional structure. Hereinafter, various structures of the cell array 330 and an operation for programming data or verifying programmed data in a plurality of memory cells included in the cell array 330 will be specifically described.

FIG. 4 illustrates a semiconductor device according to an embodiment of the present disclosure.

Referring to FIG. 4, the semiconductor device can include a high voltage source circuit 210, a switching circuit 230, a control logic 220, and a target circuit 240. Herein, the target circuit 240 included based on the design of the semiconductor device can perform internal operations using the high-level voltage VPP. Examples of the target circuit 240 that can perform internal operations by receiving the high-level voltage VPP or a high current can include a memory device, a memory system, a charging device, a power device, or a driving device which is included or used in home appliances, automobiles, communications, and industry.

The high-level voltage source circuit 210 can output the high-level voltage VPP that has a level several times (e.g., 3 to 4 times) higher or greater than the power supply voltage VCC. According to an embodiment, the high-level voltage source circuit 210 can receive the high-level voltage VPP from an outside (e.g., an external device) and transfer the high-level voltage VPP to the switching circuit 230. In another embodiment, the power supply voltage VCC is input to the high-level voltage source circuit 210, and the high-level voltage source circuit 210 can use (e.g., pump) the power supply voltage VCC to generate the high-level voltage VPP.

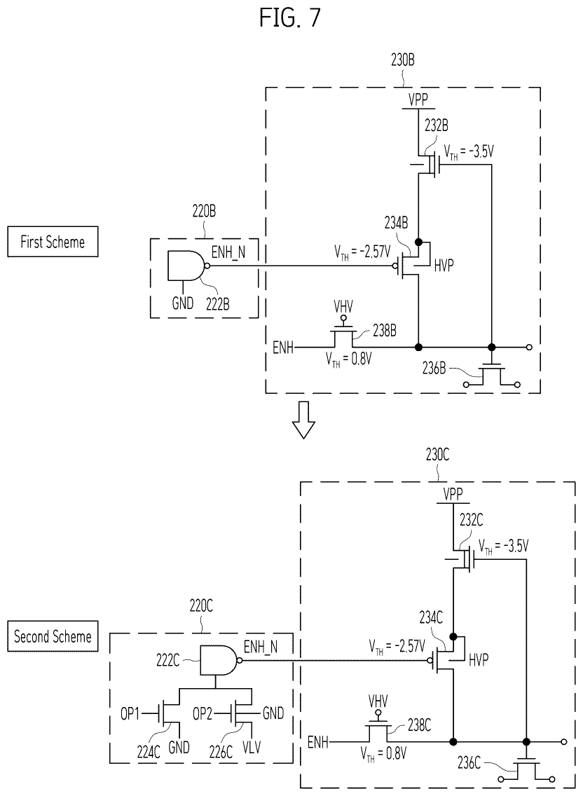

The switching circuit 230 can determine whether to transmit the high-level voltage VPP transmitted from the high-level voltage source circuit 210 to the target circuit 240. The switching circuit 230 can determine whether to transmit the high-level voltage VPP in response to a control signal CS output from the control logic 220. According to an embodiment, the switching circuit 230 can include the PMOS transistor described in FIG. 1. In another embodiment, the switching circuit 230 can include a plurality of transistors. An internal configuration of the switching circuit 230 is described below with reference to FIG. 7.

The control logic 220 can output the control signal CS used for controlling the switching circuit 230. According to an embodiment, the control logic 220 can be applied with the power supply voltage VCC and the ground voltage GND. A level of the control signal CS output by the control logic 220 can swing or transition between a first voltage level VLV and a second voltage level VHV. According to an embodiment, the level of the control signal CS can swing or transition between a ground voltage level GND and the second voltage level VHV. The control logic 220 can adaptively adjust the level of the control signal CS.

For example, a PMOS transistor can be included in the switching circuit 230. The PMOS transistor can be turned off by the control signal CS having the second voltage level VHV. When the PMOS transistor is turned off, the switching circuit 230 might not transmit the high-level voltage VPP to the target circuit 240. Conversely, the PMOS transistor can be turned on by the control signal CS having the ground voltage level GND or the first voltage level VLV. When the PMOS transistor is turned on, the switching circuit 230 can transmit the high-level voltage VPP to the target circuit 240.

Referring to FIG. 1 and FIG. 4, when the PMOS transistor is turned on by the ground voltage level GND and transmits the high-level voltage VPP, the negative bias thermal instability (NBTI) effect could occur. Therefore, the control logic 220 can turn on the PMOS transistor that switches the high-level voltage VPP by the first voltage level VLV instead of the ground voltage level GND. The first voltage level VLV can be lower than the second voltage level VHV. According to an embodiment, the first voltage level VLV can be greater than the ground voltage level GND and less than 10% of the level of the high-level voltage VPP. For example, when the power supply voltage VCC has a level ranging from 2.5 V to 5 V, the high-level voltage VPP could have a level of 20 V or higher. At this time, the second voltage level VHV can be substantially equal to the level of the power supply voltage VCC, and the first voltage level VLV can be greater than 0 V and less than 2 V. By using the first voltage level VLV instead of the ground voltage level GND, a voltage (e.g., Vgs) between the gate and the source of the PMOS transistor could be reduced. Through this scheme, the negative bias thermal instability (NBTI) effect occurring in the PMOS transistor could be reduced.

According to an embodiment, the first voltage level VLV can be adjustable based on the levels of the power supply voltage VCC and the high-level voltage VPP. The control logic 220 can adjust the first voltage level VLV in response to the level of the high-level voltage VPP output from the high-level voltage source circuit 210 and then output the first voltage level VLV to the switching circuit 230.

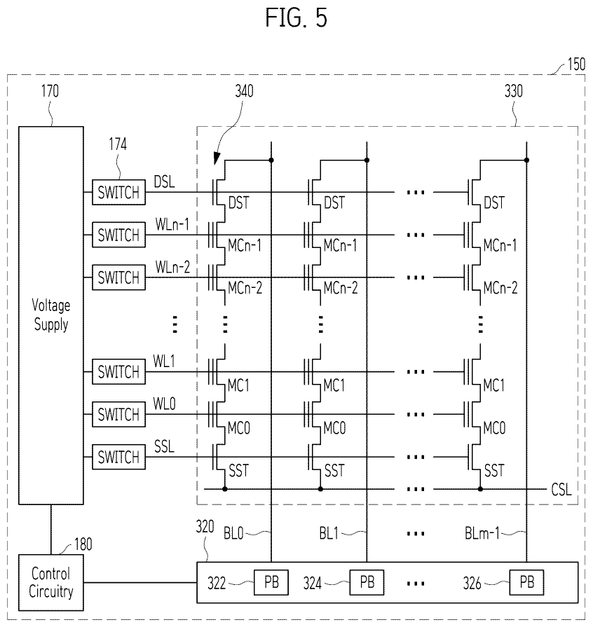

FIG. 5 illustrates a memory device 150 that includes a memory cell array circuit formed in a memory die according to an embodiment of the present disclosure.

Referring to FIG. 5, the memory device 150 may include at least one memory group 330 having a plurality of cell strings 340. Each cell string 340 may include a plurality of non-volatile memory cells MC0 to MCn-1 connected to a respective bit line of a plurality of bit lines BL0 to BLm-1. The cell strings 340 are disposed in respective columns of the memory group 330, and each cell string 340 can include at least one drain select transistor DST and at least one source select transistor SST. The non-volatile memory cells MC0 to MCn-1 of each cell string 340 may be connected in series between a drain select transistor DST and a source select transistor SST. Each of the non-volatile memory cells MC0 to MCn-1 may be configured as a multi-level cell (MLC) that stores a data item having plural bits per cell. The cell strings 340 may be electrically connected to corresponding bit lines of the bit lines BL0 to BLm-1.

In an embodiment, the memory group 330 may include NAND-type flash memory cells MC0 to MCn-1. In another embodiment, the memory group 330 can be implemented as a NOR-type flash memory, a hybrid flash memory in which at least two different types of memory cells are mixed or combined, or a one-chip NAND flash memory in which a controller is embedded in a single memory chip. In an embodiment, the memory group 330 can include a flash memory cell including a charge trap flash (CTF) layer that includes a conductive floating gate or insulating layer.

According to an embodiment, the memory device 150 shown in FIG. 5 can include at least one memory block. The memory group 330 can have a two-dimensional (2D) or three-dimensional (3D) structure. For example, each of the memory blocks in the memory device 150 may be implemented as a 3D structure, for example, a vertical structure. Each of the memory blocks may have a three-dimensional structure extending along first to third directions, for example, an x-axis direction, a y-axis direction, and a z-axis direction.

The memory group 330 including at least one memory block can be coupled to a plurality of bit lines BL, a plurality of string select lines SSL, a plurality of drain select lines DSL, a plurality of word lines WL, a plurality of dummy word lines DWL, and a plurality of common source lines CSL. In one embodiment, the memory group 330 can include a plurality of NAND strings NS which, for example, may respectively correspond to cell strings 340. Each NAND string NS may include a plurality of memory cells MC and may be connected to a respective bit line of the bit lines BL. In addition, the string select transistor SST of each NAND string NS may be connected to a common source line CSL, and the drain select transistor DST of each NAND string NS can be connected to a corresponding bit line BL. In each NAND string NS, the memory cells MC may be arranged between the string select transistor SST and the drain select transistor DST.

The memory device 150 may include a voltage supply circuit 170 which can supply a word line voltage e.g., one or more predetermined voltages such as a program voltage, a read voltage, and a pass voltage, for respective word lines of the word lines according to an operation mode, or may supply a voltage to a bulk, e.g., a well region, in which each memory block including the memory cells MC are formed. In this case, a voltage generating operation of the voltage supply circuit 170 may be performed under a control of a control circuitry 180. Also, the voltage supply circuit 170 may generate a plurality of variable read voltages to distinguish a plurality of data items from each other.

In response to the control of the control circuitry 180, one of the memory blocks (or sectors) of the memory cell array may be selected, and one of the word lines of the selected memory block may be selected. Word line voltages may be supplied to the selected word line and the unselected word line of the memory group 330, individually. The voltage supply circuit 170 may include a voltage generation circuit for generating target voltages having various levels, which are applicable to word lines of the memory group 330.

Referring to FIG. 5, the memory device 150 can further include a switch 174 between the voltage supply circuit 170 and at least one drain select line DSL, at least one source select line SSL, and the plurality of word lines WL0 to WLn-1 in the cell array 330. According to an embodiment, the switch 174 can be included in the voltage supply circuit 170.

The switch 174 can operate based on a control signal that swings to a different level in response to a voltage level output from the voltage supply circuit 170 to the plurality of word lines WL0 to WLn-1. According to an embodiment, the switch 174 can correspond to the switching means 230 described in FIG. 4. For example, when the switch 174 transmits the high-level voltage, such as the program voltage, the erase voltage, or the pass voltage, to the plurality of word lines WL0 to WLn-1, a control signal of the switch 174 can swing between the first voltage level VLV and the second voltage level VHV. When the switch 174 transmits a low-level read voltage to the plurality of word lines WL0 to WLn-1, the control signal of the switch 174 can swing between the ground voltage level GND and the second voltage level VHV.

The memory device 150 may also include a read/write circuit 320 controlled by the control circuitry 180. The read/write circuit 320 may operate as a sense amplifier or a write driver according to an operation mode. For example, in a verify operation and a read operation, the read/write circuit 320 may operate as a sense amplifier for reading the data item from the memory cell array. In a program operation, the read/write circuit 320 may operate as a write driver that controls potentials of bit lines according to a data item to be stored in the memory cell array. The read/write circuit 320 may receive the data item to be programmed to the cell array from page buffers during the program operation. The read/write circuit 320 can drive bit lines based on the input data item. To this end, the read/write circuit 320 may include a plurality of page buffers (PB) 322, 324, 326, with each page buffer corresponding to each column or each bit line, or each column pair or each bit line pair. According to an embodiment, a plurality of latches may be included in each of the page buffers 322, 324, 326. According to an embodiment, the number of latches or page buffers coupled to each bit line can be equal to, or greater than, the number of bits of data stored in the memory cells MC.

The page buffers 322, 324, 326 may be coupled to a data input/output device, e.g., a serialization circuit or a serializer, through a plurality of buses. When each of the page buffers 322, 324, 326 is coupled to the data input/output device through different buses, a delay that may occur in data transmission from the page buffers 322, 324, 326 can be reduced. For example, each page buffer 322, 324, 326 can perform the data transmission without a waiting time.

According to an embodiment, the memory device 150 may receive a write command, write data, and information, e.g., a physical address, regarding a location in which the write data is to be stored. The control circuitry 180 causes the voltage supply circuit 170 to generate a program pulse, a pass voltage, etc., used for a program operation performed in response to a write command, and to generate one or more voltages used for a verification operation performed after the program operation.

When a multi-bit data item is programmed in non-volatile memory cells included in the memory group 330, the error rate might be higher than that when a single-bit data item is stored in the non-volatile memory cells. For example, an error in the non-volatile memory cells may be induced due to cell-to-cell interference (CCI). In order to reduce error in the non-volatile memory cells, a width (deviation) of a threshold voltage distribution, corresponding to stored data items between the non-volatile memory cells, should be reduced.

To this end, the memory device 150 can perform an incremental step pulse programming (ISPP) operation to effectively make a narrow threshold voltage distribution of the non-volatile memory cells. In an embodiment, the memory device 150 can use the ISPP operation for multi-step program operations. For example, the memory device 150 may divide a program operation into a Least Significant Bit (LSB) program operation and a Most Significant Bit (MSB) operation according to a predetermined order between the non-volatile memory cells or pages.

A multi-bit value programmed in a memory cell in a NAND flash memory (e.g., NAND-type flash memory cells MC0 to MCn-1 in the memory group 330) can be determined based on a threshold voltage window or a threshold voltage distribution to which the cell's threshold voltage belongs. As a size of each memory cell shrinks and more bits (e.g., 3-bit, 4-bit, or 5-bit) of data are programmed per memory cell, a width of the threshold voltage window used to represent each multi-bit value becomes narrower, increasing an error rate when determining the multi-bit value stored in the memory cell. This is because process variations become more widespread when an amount of charge stored in each memory cell decreases with a feature size, resulting in large differences in threshold voltages of different memory cells storing the same value. As a result, it becomes increasingly difficult to determine to which value a threshold voltage of a memory cell corresponds.

According to an embodiment, the control circuitry 180 may include a read retry table (RRT). The RRT may be stored in the memory device 150. A read error may occur in a process of applying a read voltage to a non-volatile memory cell in the memory device 150 through a word line and reading data stored in the non-volatile memory cell. The control circuitry 180 in the memory device 150 may manage information regarding a read retry mechanism for resolving read errors. One of the information regarding the read retry mechanism is the read RRT. The read retry mechanism uses the RRT for a recorded location where the error has occurred, so that the memory device 150 can ensure data integrity by applying an appropriate correction value (e.g., changing a read voltage level) when re-reading.

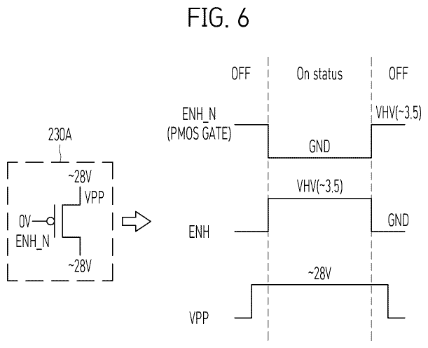

FIG. 6 illustrates an operation of a first switching device according to one embodiment of the present disclosure.

Referring to FIG. 6, the first switching device 230A can include a PMOS transistor. The first switching device 230A can transmit a high-level voltage VPP in response to a first inverted control signal ENH_N. Here, the high-level voltage VPP can have a level several times higher or greater than the power supply voltage. For example, the high-level voltage VPP can be a 28 V when the power supply voltage is 3.5 V.

A first control signal ENH used for controlling the first switching device 230A can transition or swing from a ground voltage level GND to a second voltage level VHV or from the second voltage level VHV to the ground voltage level GND. The second voltage level VHV can have a level of about 3.5 V. The first inverted control signal ENH_N in which the first control signal ENH is inverted can be applied to a gate (GATE) of the PMOS transistor in the first switching device 230A.

The PMOS transistor in the first switching device 230A can be turned on by the first inverted control signal ENH_N having the ground voltage level GND and turned off by the first inverted control signal ENH_N having the second voltage level VHV.

When the ground voltage level GND of 0 V is applied to the gate GATE of the PMOS transistor and the PMOS transistor is turned on, the performance of the first switching device 230A could deteriorate due to the negative bias thermal instability (NBTI) effect because the high-level voltage VPP is applied or biased to a junction and a well of the PMOS transistor for a long time, which could not be ignored.

FIG. 7 illustrates configuration of a second switching device and a third switching device according to an embodiment of the present disclosure. Specifically, FIG. 7 illustrates the difference in the negative bias thermal instability (NBTI) effect that occurs in the second switching device (First Scheme) and the third switching device (Second Scheme) having different configurations.

Referring to FIG. 7, the second switching device (First Scheme) can include a second control circuit 220B and a second switching unit 230B.

The second control circuit 220B can output a first control signal ENH and a first inverted control signal ENH_N to the second switching unit 230B. The second switching unit 230B can determine whether to transmit a high-level voltage VPP in response to the first control signal ENH and the first inverted control signal ENH_N.

Here, the first control signal ENH and the first inverted control signal ENH_N can have an inverted logical state with each other. In addition, the high-level voltage VPP can have a voltage level that is several times that of the second voltage level VHV. The second voltage level VHV can have a level substantially the same as the power supply voltage level VCC described in FIG. 4.

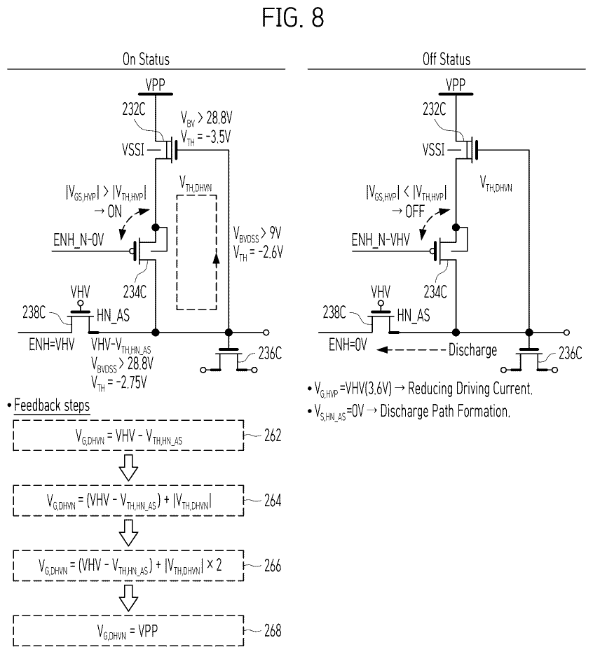

The second switching unit 230B can include a plurality of transistors 232B, 234B, 236B. The second switching unit 230B can include a loop circuit that is activated in response to the first inverted control signal ENH_N and a switch 238B that is configured to discharge the loop circuit in response to the first control signal ENH. For example, the loop circuit can include one PMOS transistor 234B and two NMOS transistors 232B, 236B. According to an embodiment, the PMOS transistor 234B configured to determine whether to transmit the high-level voltage VPP in response to the first inverted control signal ENH_N can have a threshold voltage V_{TH} of 2.57 V. Among the two NMOS transistors 232B, 236B, one transistor 232B can determine whether to transfer the high-level voltage VPP to the PMOS transistor with a threshold voltage V_{TH} of 3.5 V, and the other transistor 236B can have an output terminal connected to a gate so that the high-level voltage VPP output through the output terminal could be output stably. The second switching unit 230B can include the switch 238B that is configured to selectively connect the first control signal ENH and the loop circuit in response to the second voltage level VHV. The switch 238B can include a PMOS transistor having a threshold voltage V_{TH} of 0.8 V. The specific operation of the second switching unit 230B will be described later with reference to FIG. 8.

The second control circuit 220B can include at least one logic gate or at least one element. For example, a NAND gate 222B can be included in the output terminal of the second control circuit 220B. The power supply voltage level VCC and the ground voltage level GND can be applied to the output terminal of the second control circuit 220B, and the first inverted control signal ENH_N output by the second control signal 220B can have a level of the power supply voltage level VCC or the ground voltage level GND. That is, the first inverted control signal ENH_N can transition from a power supply voltage level VCC to the ground voltage level GND or from the ground voltage level GND to the power supply voltage level VCC.

Referring to FIG. 7, the third switching device (Second Scheme) can have a structure that improves the second switching device (First Scheme). The third switching device (Second Scheme) can include a third control circuit 220C and a third switching unit 230C. The third switching unit 230C can include substantially the same configuration as the second switching unit 230B. The configuration and operation of the third switching unit 230C will be described later with reference to FIG. 8.

The third control circuit 220C can have a different structure from the second control circuit 220C. The third control circuit 230C can include at least one logic gate or at least one element. For example, a NAND gate 222C can be included in the output terminal of the third control circuit 220C. The NAND gate 222C can be connected to a ground voltage switch 224C and a first voltage switch 226C.

The ground voltage switch 224C can transmit the ground voltage level GND to the NAND gate 222C in response to a first selection signal OP1. The first voltage switch 226C can transmit the first voltage level VLV to the NAND gate 222C in response to a second selection signal OP2. According to an embodiment, each of the ground voltage switch 224C and the first voltage switch 226C can include an NMOS transistor. The ground voltage level GND could be applied to bodies of the NMOS transistors included in the ground voltage switch 224C and the first voltage switch 226C.

In response to the activation of the first selection signal OP1 and the second selection signal OP2, a swing range of the first inversion control signal ENH_N output from the NAND gate 222C can vary. For example, when the first selection signal OP1 is activated, the first inversion control signal ENH_N can transition from the power supply voltage level VCC to the ground voltage level GND or from the ground voltage level GND to the power supply voltage level VCC. When the second selection signal OP1 is activated, the first inverted control signal ENH_N can transition from the power supply voltage level VCC to the first voltage level VLV or from the first voltage level VLV to the power supply voltage level VCC.

According to an embodiment, only one of the first selection signal OP1 and the second selection signal OP2 could be activated. For example, the first selection signal OP1 and the second selection signal OP2 can be signals that are inverted from each other.

Further, according to an embodiment, the first selection signal OP1 or the second selection signal OP2 can be activated only when the third control circuit 230C outputs the first control signal ENH or the first inverted control signal ENH_N.

FIG. 8 illustrates an operation of a third switching device described in FIG. 7. Specifically, FIG. 8 describes the operation of the third switching unit 230C when the first inversion control signal ENH_N transitions from the second voltage level VHV to the ground voltage level GND (e.g., 0V) or from the ground voltage level GND (e.g., 0V) to the second voltage level VHV in response to the first selection signal OP1.

Referring to FIG. 8, when the first inversion control signal ENH_N is 0V which is the same as the ground voltage level GND, the third switching unit 230C could become a turn-on state (On Status) for transferring the high-level voltage VPP. On the other hand, when the first inversion control signal ENH_N is the second voltage level VHV, the third switching unit 230C could become a turn-off state (Off Status) in which the high-level voltage VPP might be not transmitted. The operation of the third switching unit 230C can be described by the change in a potential V_{G,DHVN} of the loop circuit. In the turn-on state (On Status), the first control signal ENH could be the second voltage level VHV. The switch 238C of the third switching unit 230C could be turned on by the second voltage level VHV, and the first control signal ENH of the second voltage level VHV can be connected to the loop circuit. The potential VG, DHVN of the loop circuit could be a value (=VHV−V_{TH,HN_AS}) obtained by subtracting the threshold voltage V_{TH, HN_AS} of the switch 238C from the second voltage level VHV (operation 262). When the potential VG, DHVN of the loop circuit becomes the subtracted value (=VHV−V_{TH, HN_AS}), the NMOS transistor 232C is turned on, and the potential VG, DHVN of the loop circuit can increase by the value V_{TH, DHVN} transmitted by the NMOS transistor 232C (operation 264). According to an embodiment, the high-level voltage VPP can be greater than 28.8 V, a body voltage of the NMOS transistor 232C can be an internal ground voltage VSS, and the threshold voltage V_{TH} of the NMOS transistor 232C can be −3.5 V.

As the potential V_{G, DHVN} of the loop circuit increases, the voltage V_{GS, HVP} between the source and the gate of the PMOS transistor 234C becomes greater than the threshold voltage V_{TH, HVP} of the PMOS transistor 234C. The same level can be applied to the source and the body of the PMOS transistor 234C. The breakdown voltage V_{BVDSS} of the PMOS transistor 234C can be greater than 9 V, and the threshold voltage V_{TH} of the PMOS transistor 234C can be −2.6 V. When the voltage V_{GS, HVP} between the gate and the source of the PMOS transistor 234C becomes greater than the threshold voltage V_{TH, HVP} of the PMOS transistor 234C (e.g., |H_{GS,HVP}|>|V_{TH,HVP}|) , the PMOS transistor 234C can be turned on. As a result, the potential V_{G, DHVN} of the loop circuit can increase further (operation 266).

The potential V_{G, DHVN} of the loop circuit increases further, and the potential V_{G, DHVN} of the loop circuit can reach the high-level voltage VPP (operation 268). Because the breakdown voltage V_{BVDSS} of the switch 238C is 28.8 V or higher (e.g., greater than or equal to the level of the high-level voltage VPP, the potential V_{G, DHVN} of the loop circuit might not leak or be discharged through the switch 238C. This scheme can support that the potential V_{G, DHVN} of the loop circuit increases during the turn-on state (On Status).

For the turn-off state (Off Status), the first inverted control signal ENH_N can transition to the second voltage level VHV. When the first inverted control signal ENH_N transitions from the ground voltage (e.g., 0 V) to the second voltage level VHV, a current flowing through the PMOS transistor 234C could decrease. When the voltage V_{GS, HVP} between the gate and the source of the PMOS transistor 234C becomes less than the threshold voltage V_{TH, HVP} of the PMOS transistor 234C (e.g., |V_{GS,HVP}|<|V_{TH,HVP}|) , the PMOS transistor 234C can be turned off (OFF).

In addition, the first control signal ENH having a ground voltage level (e.g., 0 V) is connected to the loop circuit through the switch 238C (V_{S,HN_AS}=0 V), so that a path (e.g., Discharge path) through which the potential of the loop circuit could be discharged can be formed. Through this, the potential of the loop circuit could be lowered from the high-level voltage VPP to the ground voltage level (e.g., 0 V).

FIG. 8 illustrates a case in which the first inverted control signal ENH_N transitions from the second voltage level VHV to the ground voltage level GND or from the ground voltage level GND to the second voltage level VHV. Hereinafter, the operations of the second switching device (First Scheme) and the third switching device (Second Scheme) are compared and described when a swing range of the first inversion control signal ENH_N changes.

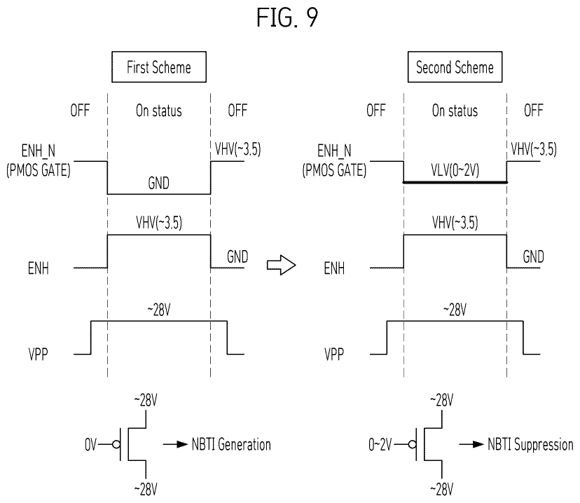

FIG. 9 illustrates operations of a second switching device and a third switching device according to an embodiment of the present disclosure. Specifically, FIG. 9 compares and describes the operation of the second switching device (First Scheme) based on the first inverting control signal ENH_N transitioning from the second voltage level VHV to the ground voltage level GND or from the ground voltage level GND to the second voltage level VHV and the operation of the third switching device (Second Scheme) based on the first inverting control signal ENH_N transitioning from the second voltage level VHV to the first voltage level VLV or from the first voltage level VLV to the second voltage level VHV.

Referring to FIG. 9, the first inverting control signal ENH_N used in the second switching device (First Scheme) can transition from the second voltage level VHV to the ground voltage level GND or from the ground voltage level GND to the second voltage level VHV. The first control signal ENH can have a logic value opposite to that of the first inverting control signal ENH_N. Similar to the first inverting control signal ENH_N, the first control signal ENH can transition from the ground voltage level GND to the second voltage level VHV or from the second voltage level VHV to the ground voltage level GND. Herein, the second voltage level VHV can be equal to or less than 3.5 V, and the high-level voltage VPP can be equal to or less than 28 V.

Referring to FIG. 1 and FIG. 7 to FIG. 9, the negative bias thermal instability (NBTI) effect may occur in the PMOS transistor 234B included in the second switching device (First Scheme), which may deteriorate the operating performance of the second switching device (First Scheme).

On the other hand, the first inversion control signal ENH_N used in the third switching device (Second Scheme) can transition from the second voltage level VHV to the first voltage level VLV or from the first voltage level VLV to the second voltage level VHV. Here, the first voltage level VLV can be at a level greater than the ground voltage GND of 0 V and less than 2 V. In addition, the first control signal ENH can have a logic value opposite to that of the first inverted control signal ENH_N, but the first control signal ENH can transition from the ground voltage level GND to the second voltage level VHV or from the second voltage level VHV to the ground voltage level GND. That is, the first control signal ENH and the first inverted control signal ENH_N have opposite logic values that are inverted from each other, but voltage swing ranges of the first control signal ENH and the first inverted control signal ENH_N could be different. Here, the second voltage level VHV can be equal to or less than 3.5 V, and the high-level voltage VPP can be equal to or less than 28 V.

Referring to FIG. 1 and FIG. 7 to FIG. 9, the negative bias thermal instability (NBTI) effect could be alleviated, reduced, or avoided in the PMOS transistor 234C included in the third switching device (Second Scheme), thereby avoiding deterioration of the operating performance of the third switching device (Second Scheme) or maintaining the operating performance of the third switching device (Second Scheme).

According to an embodiment, the first voltage level VLV can have a level that could be adaptively adjusted in response to levels of the power supply voltage VCC and the high-level voltage VPP.

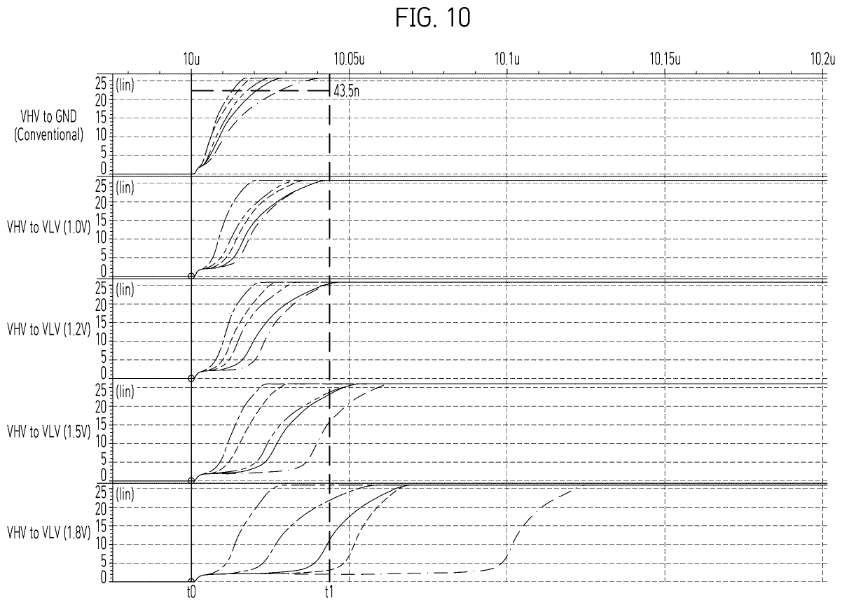

FIG. 10 illustrates a first simulation result for the change in an output terminal of a switching device according to an embodiment of the present disclosure. Specifically, FIG. 10 illustrates an operation result (e.g., a switching/operation speed of the switching device) in which an output terminal of the switching means (e.g., the drain of the PMOS transistor 234C included in the third switching unit 230C) rises from the ground voltage GND to the high-level voltage VPP.

Referring to FIG. 10, when the voltage swing range of the first inverting control signal ENH_N applied to the gate of the PMOS transistor 234C included in the third switching unit 230C is different, the operation speed for the output terminal of the switching device to reach a level of the high-level voltage VPP from the ground voltage GND is shown when a delay of the first inverting control signal ENH_N and the PMOS transistor 234C is changed (e.g., estimated by adding three times a standard deviation to an average (e.g., 3-sigma sweep simulation)). FIG. 10 illustrates five examples including a first case where the first inverting control signal ENH_N transitions between the ground voltage level GND and the second voltage level VHV, a second case where the first inverting control signal ENH_N transitions between the first voltage level VLV and 1 V as the second voltage level VHV, a third case where the first inverting control signal ENH_N transitions between the first voltage level VLV and 1.2 V as the second voltage level VHV, a fourth case where the first inverting control signal ENH_N transitions between the first voltage level VLV and 1.5 V as the second voltage level VHV, and a fifth case where the first inverting control signal ENH_N transitions between the first voltage level VLV and 1.8 V as the second voltage level VHV.

The operating margin of the switching means through which the high-level voltage VPP is transmitted when the first inverting control signal ENH_N transitions between the ground voltage level GND and the second voltage level VHV can be set from a first time point t0 to a second time point t1. For example, a time length from the first time point t0 to the second time point t1 can be approximately 43.5 ns. In the five cases described above, when the first voltage level VLV is greater than 0 V and less than 1.2 V, an operation margin of the switching means could be satisfied. However, when the first voltage level VLV is 1.5 V or 1.8 V, the operation margin of the switching means could be satisfied or might not be satisfied depending on a transition speed of the first inversion control signal ENH_N.

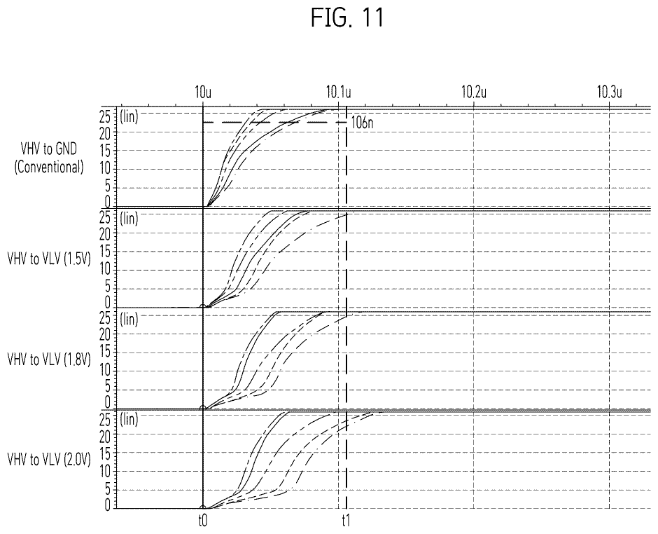

FIG. 11 illustrates a second simulation result for the change in an output terminal of a switching device according to an embodiment of the present disclosure. Specifically, FIG. 11 describes an operation result (e.g., an operating speed of the switching means) of a procedure in which the output terminal of the switching means (e.g., a drain region of the PMOS transistor 234C included in the third switching unit 230C) rises from a negative voltage level, which is lower than the ground voltage level GND, to the high-level voltage VPP.

Referring to FIG. 11, when the voltage swing range of the first inverting control signal ENH_N applied to the gate of the PMOS transistor 234C included in the third switching unit 230C is different, the operation speed at which the drain region of the PMOS transistor 234C in the third switching unit 230C reaches to the high-level voltage VPP from the negative voltage level could be changed based on different delays of the first inverting control signal ENH_N and the PMOS transistor 234C (e.g., estimated by adding three times the standard deviation to the average (e.g., 3-sigma sweep simulation)). FIG. 10 illustrates four cases including a first case in which the first inverting control signal ENH_N transitions between the ground voltage level GND and the second voltage level VHV, a second case in which the first inverting control signal ENH_N transitions between the first voltage level VLV of 1.5 V and the second voltage level VHV, a third case in which the first inverting control signal ENH_N transitions between the first voltage level VLV of 1.8 V and the second voltage level VHV, and a fourth case in which the first inverting control signal ENH_N transitions between the first voltage level VLV and the second voltage level VHV of 2.0 V.

The operating margin of the switching means through which the high-level voltage VPP is transmitted when the first inverting control signal ENH_N transitions between the ground voltage level GND and the second voltage level VHV could be set from the first time point t0 to the second time point t1. For example, the time length from the first time point t0 to the second time point t1 could be approximately 106 ns.

In the four cases, when the first voltage level VLV is 1.5 V as compared to a case of ground voltage level GND, there might not be a significant difference in the operating margin of the switching means. However, when the first voltage level VLV is 1.8 V or 2.0 V, the operating margin of the switching means could be satisfied or might not be satisfied depending on the transition speed of the first inverting control signal ENH_N.

Referring to FIGS. 10 and 11, the swing range of the first inverting control signal ENH_N, satisfying the operating margin of the third switching device (Second Scheme) while alleviating the negative bias thermal instability (NBTI) effect, could be found by reflecting the statistical estimation of the delay in the third switching device (Second Scheme). According to an embodiment, the first voltage level VLV can be set to a level of 10% or less than the level of the high-level voltage VPP. Additionally, in another embodiment, when the first voltage level VLV is set to a level less than a 5-6% level of the high-level voltage VPP, the operating margin of the third switching device (Second Scheme) could be satisfied, as well as the negative bias thermal instability (NBTI) effect could be alleviated.

As above described, According to an embodiment of the present disclosure, a semiconductor device, a memory device, or a memory system can reduce a potential difference between a gate and a junction of a switching means by adjusting a potential of a signal used for controlling the switching means configured to transmit a high-level voltage having a higher level at least three times greater than a power supply voltage, thereby reducing the negative bias thermal instability (NBTI) effect, which is a sort of deterioration phenomenon.

According to an embodiment of the present disclosure, a semiconductor device, a memory device, or a memory system can avoid or reduce the negative bias temperature instability (NBTI) effect of the switching means, thereby having an advantage of reducing or avoiding performance degradation of the switching means.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments, may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, logic, interfaces, decoders, drivers, generators and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, logic, interfaces, decoders, drivers, generators and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, logic, interfaces, decoders, drivers, generators and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments, may transform the computer, processor, controller, or other signal processing device into a special-purpose processor for performing the methods described herein.

While the embodiments of the present disclosure have been illustrated and described with respect to specific embodiments, it will be apparent to those skilled in the art in light of the present disclosure that various changes and modifications may be made to the embodiments as defined in the following claims without departing from the spirit and scope of the present disclosure. Furthermore, the embodiments may be combined to form additional embodiments.

What is claimed is:

1. A memory device comprising:
a switching unit configured to determine whether to transmit a high-level voltage having a level at least three times higher or greater than a power supply voltage; and
a control element configured to generate, for controlling the switching unit, a first control signal transitioning between a first voltage level and a second voltage level,
wherein the first voltage level is equal to a level of the power supply voltage, and
wherein the second voltage level is greater than 0 V and less than 10% of a level of the high-level voltage.

2. The memory device according to claim 1, further comprising:
at least one memory cell configured to store data;
a word line connected to the at least one memory cell and used to apply the high-level voltage transmitted through the switching unit; and
a voltage generation circuit configured to output the high-level voltage.

3. The memory device according to claim 1, wherein the switching unit comprises a PMOS transistor, and
wherein the first control signal having the first voltage level or the second voltage level is applied to a gate of the PMOS transistor.

4. The memory device according to claim 3, wherein the first control signal having the first voltage level is used for turning off the PMOS transistor, and the second control signal having the second voltage level is used for turning on the PMOS transistor.

5. The memory device according to claim 1, wherein:
the power supply voltage has a level ranging from 2.5 V to 5 V;
the high-level voltage has a level of 20 V or higher; and
the second voltage level is greater than 0 V and less than 2 V.

6. The memory device according to claim 1, wherein the second voltage level is adjustable based on the levels of the power supply voltage and the high-level voltage.

7. The memory device according to claim 1, wherein the control element is connected to a switching element configured to transmit the second voltage level to the control element in response to a selection control signal.

8. The memory device according to claim 7, wherein the switching element comprises an NMOS transistor.

9. The memory device according to claim 1, wherein the switching unit comprises:
a loop circuit which comprises a plurality of transistors and is activated in response to the second voltage; and
a switch configured to discharge the loop circuit in response to a second control signal.

10. The memory device according to claim 9, wherein the second control signal has a logical value inverted from that of the first control signal, and
wherein voltage swing ranges of the first control signal and the second control signal are different from each other.

11. A semiconductor device comprising:
a switching unit configured to determine whether to transfer a high-level voltage having a higher level at least three times greater than a power supply voltage;
a control device configured to generate, for controlling the switching unit, a control signal transitioning between a first voltage level and a second voltage level; and
a first switch configured to transfer, to the control device, a first low voltage level as the second voltage level in response to a first selection control signal, the first low voltage level being greater than a ground voltage level and less than a level of the high-level voltage.

12. The semiconductor device according to claim 11, further comprising:
a second switch configured to, in response to a second selection control signal, transfer the ground voltage level, as the second voltage level, to the control device,
wherein either the first selection signal or the second selection signal is activated.

13. The semiconductor device according to claim 12, wherein each of the first switch and the second switch comprise a NMOS transistor.

14. The semiconductor device according to claim 11, wherein the first voltage level is equal to a level of the power supply voltage.

15. The semiconductor device according to claim 11, wherein the switching unit comprises a PMOS transistor, and
wherein the control signal having the first voltage level or the second voltage level is applied to a gate of the PMOS transistor.

16. The semiconductor device according to claim 15, wherein the first control signal having the first voltage level is used for turning off the PMOS transistor, and the second control signal having the second voltage level is used for turning on the PMOS transistor.

17. The semiconductor device according to claim 11, wherein:
the power supply voltage has a level ranging from 2.5 V to 5 V;
the high-level voltage has a level of 20 V or higher; and
the second voltage level is greater than 0 V and less than 2 V.

18. The semiconductor device according to claim 11, wherein the second voltage level is adjustable based on levels of the power supply voltage and the high-level voltage.

19. A non-volatile memory device comprising:
a plurality of memory cells configured to store data;
a word line coupled to the plurality of memory cells;
a voltage generator configured to generate at least one of a pass voltage, a program voltage, and an erase voltage, each of which has a level at least three times higher or greater than a power supply voltage;
a switching unit configured to determine whether to transfer the at least one of the pass voltage, the program voltage, and the erase voltage to the word line; and
a control element configured to generate a control signal transitioning between a first voltage level and a second voltage level to control the switching unit,
wherein the first voltage level is equal to a level of the power supply voltage, and
wherein the second voltage level is greater than 0 V and less than 10% of a level of the high-level voltage.

20. The non-volatile memory device according to claim 19, wherein the switching unit comprises a PMOS transistor, and
wherein the control signal having the first voltage level or the second voltage level is applied to a gate of the PMOS transistor.

21. The non-volatile memory device according to claim 19, wherein the second voltage level is adjustable based on the levels of the power supply voltage and the high-level voltage.
